(19) United States
(12) Patent Application Publication
(10) Pub. No.: US 2003/0182609 A1
(43) Pub. Date: Sep. 25, 2003

(54) Pass gate multiplexer

(76) Inventors: Shirish Agrawal, Uttar Pradesh (IN); Ravikanth Nukala, Uttar Pradesh (IN)

Correspondence Address: WOLF GREENFIELD & SACKS, PC, FEDERAL RESERVE PLAZA, 600 ATLANTIC AVENUE, BOSTON, MA, 02210-2211, US

(21) Appl. No.: 10/351,967

(22) Filed: Jan. 27, 2003

(30) Foreign Application Priority Data
Jan. 31, 2002 (IN) 80/DEL/2002

(51) Int. Cl. G01R 31/28

(52) U.S. Cl. 714/724

(57) ABSTRACT

An improved pass gate multiplexer including a decoder for selecting one out of a plurality of pass gates including a weak pull-up at the output of the multiplexer for providing a defined logic level when all the pass gates are deselected and circuitry for enabling or disabling the decoder thereby facilitating the testing of the internal select signals using externally generated test pattern vectors. The instant invention also provides a method for improving a pass gate multiplexer.

### BACKGROUND OF THE INVENTION

1. Field of the Invention

This invention relates to an improved pass gate multiplexer, particularly to detection of stuck-at faults in high performance structures like pass gate multiplexers.

2. Discussion of the Related Art

Automatic Test Pattern Generation (ATPG) is an effective way to automatically test electronic circuits including integrated circuits. For testing of digital circuits, the process commonly employs a “stuck-at fault” model to emulate physical defects that may occur during fabrication of an integrated circuit. Such models represent stuck-at defects as nodes or pins within the circuit that are continually held (i.e. “stuck”) at a single logic value, either a 0 or a 1. Each pin in the circuit is individually subjected to a single stuck-at fault condition. A complete set of test vectors is applied to the integrated circuit under test and the simulation results so obtained are compared with the simulation results of an identical “good” circuit (i.e. with no injected faults). If, for any one of the test vectors, the output of the faulted circuit exhibits a “hard” difference (i.e. “1” expected but “0” detected, or vice versa) from the output of the good circuit, then the stuck-at fault condition is detected.

Pass-gate multiplexers are a common circuit element in several integrated circuits. The usage of these multiplexers severely impacts the ATPG fault-coverage of the design. Consider a typical two input pass gate multiplexer (FIG. 1 of the accompanying drawings). D1, D2 are data inputs of the multiplexer. S1, & S2 are decoded selects for the pass gates. The data inputs are adequate for ATPG purposes, i.e. they are both observable and controllable. The selects however, are not controllable or observable. This will cause a drastic fall in the fault coverage for the logic in the fanin/fanout of these select lines.

To test a stuck-at 1 fault on S1, a ‘0’ is driven on S1. Since the selects have to be fully decoded S2 will be logic 1. If there is a stuck-at 1 fault on S1, both transistors T1 & T2 will be on, hence there will be contention on Output O, and output will be in an “X” (unknown) state. None of the ATPG tools can observe a X or a Z (High impedance) state. The ATPG tools expects outputs to be either 0 or 1. Therefore, a stuck-at 1 fault is not testable on S1 select. The same holds true for select S2. Similarly to test a stuck-at 0 on S1, a ‘1’ is driven on S1. S2 will have to be logic 0. If there is a stuck-at-0 fault on S1, both transistors T1 & T2 will be switched off, hence the output will be high-Z state. Again the ATPG tools cannot identify a High-Z state. Therefore, a stuck-at ‘0’ fault is also not testable on S1. The same holds true for select S2. Thus the selects for the pass gate multiplexers are unobservable for ATPG. This results in a severe reduction of Fault coverage.

The same explanation is true for pass gate multiplexers with any number of inputs.

To have good fault coverage, the pass gate multiplexer is sometimes modeled, as a simple nand-nor multiplexer. Using this, the ATPG tools will give a high fault coverage figure but the vectors generated will not be able test the stuck-at faults on the selects of multiplexer and the preceding logic.

Therefore, a methodology to test these structures is very critical for silicon testing.

U.S. Pat. No. 6,185,713 describes a method and approach for improving fault coverage of a tri-state bus holder. However, this patent does not address the specific issues pertaining to testing of pass gate multiplexers.

### SUMMARY OF THE INVENTION

An object of this invention is to provide an improved pass gate multiplexer that is fully testable using externally generated test pattern vectors.

To achieve these and other objects, the invention provides a pass gate multiplexer, comprising:

a decoder for selecting one out of a plurality of pass gates;

a weak pull-up at an output of said multiplexer for providing a defined logic level when all the pass gates are deselected; and

means for enabling or disabling said decoder,

to facilitate testing of internal select signals using externally generated test pattern vectors.

The said means is an electronic circuit connected to said decoder for enabling or disabling its output by an external enable/disable signal.

The said weak pull-up is controllable by logic signals so that it is disabled during normal operation and enabled only during testing.

The invention also provides a method of operating a pass gate multiplexer comprising:

providing a weak pull-up at an output of said multiplexer for obtaining a defined logic level when all the pass gates are deselected, and

making the internal decoder controllable by an enable/disable signal,

to facilitate the testing of the internal select signals using externally generated test pattern vectors.

The controlling of said weak pull-up is such that it is disabled during normal operation and enabled only during testing.

### BRIEF DESCRIPTION OF THE DRAWINGS

The invention will now be described with reference to the accompanying drawings.

FIG. 1 shows a two-input pass gate multiplexer, according to the prior art;

FIG. 2 shows an improved pass gate multiplexer, according to the present invention;

FIG. 3 shows Stuck-at 0 fault at S1; and

FIG. 4 shows Stuck-at 1 fault at S1.

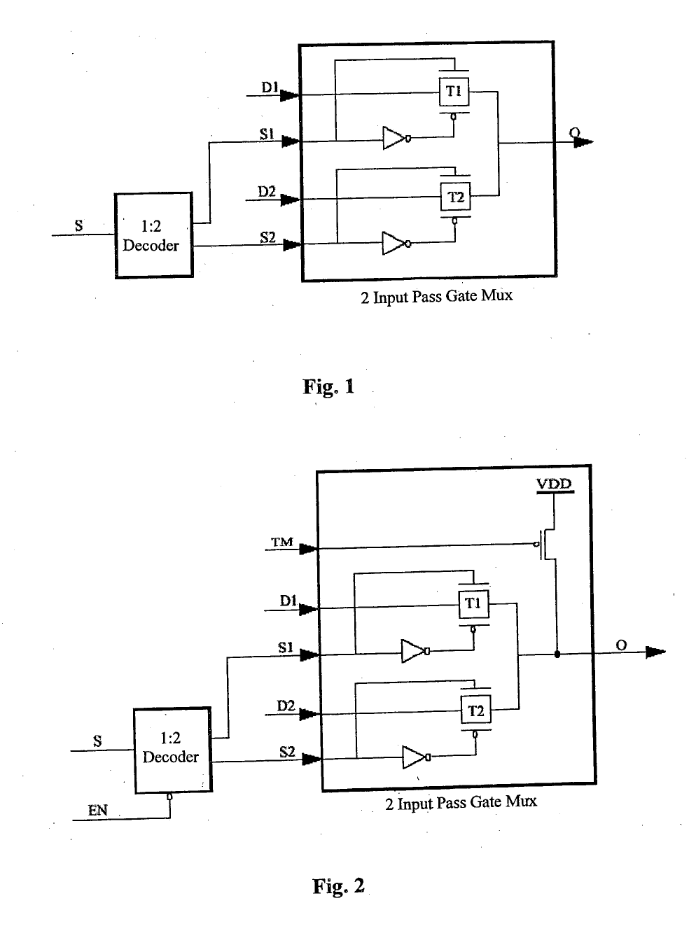

### DETAILED DESCRIPTION

In the invention a weak controllable pull-up is attached at the output of the multiplexer and the select decoder is replaced with a decoder with an enable. That is, if the enable is logic 0, the outputs of decoder (selects of multiplexer) will all be logic 0.

FIG. 2 shows one embodiment of the invention. From the prior art the data input pins D1, D2 are observable & controllable, hence are testable. This circuit makes the selects of the multiplexer also observable & controllable. To test for stuck-at 0 fault at S1, S1 is driven as logic one through the decoder. Hence S2 is driven to logic 0. The Data pin D1 is also driven to 0. If there is a stuck-at 0 fault on S1, both transistors T1 & T2 will be switched off, output will be pulled up by the weak pull-up to logic 1, if there is no stuck-at 0 fault on S1 (i.e S1 is logic 1), transistor T1 will be switched on, and transistor T2 will be switched off. Hence D1 will be transferred to output. Thus 0 will be logic 0. This is understood by the existing ATPG tools.

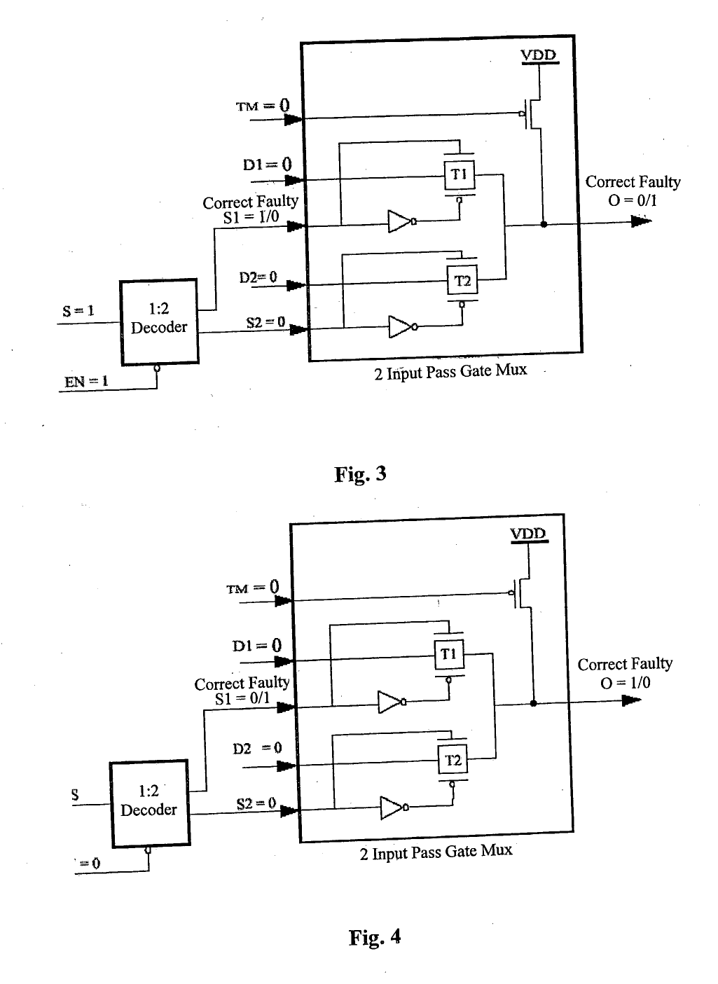

FIG. 3 illustrates the above. The same holds true for observing a logic 1 on S1. The same explanation is true for testing stuck-at 0 fault at S2.

To test for stuck-at fault 1 at S1, we drive S1 as logic 0, through the enable of the decoder. So both S1 & S2 are logic 0. The Data pin D1 is again driven to 0. If there is a stuck-at fault 1 on S1, transistor T1 is ON & T2 is OFF, hence output is equal to D1, i.e. logic 0. If there is no stuck-at fault 1 on S1, both transistors T1 & T2 are off, output will be logic 1 (due to the pull-up). FIG. 4 illustrates the above. The same holds true for observing a logic 0 on S1. The above explanation is true for testing stuck-at fault 1 at S2

Thus both S1 & S2 are made fully observable and controllable, hence completely testable. This results in the drastic improvement in fault-coverage of the designs using pass gate multiplexers. The same explanation is true for pass-gate multiplexers with any number of inputs. The proposed scheme is tested using Tetramax ATPG tool. There was a drastic improvement in fault coverage. In principle the proposed scheme can be used with any ATPG tool.

Since the pull-up's are controllable, this solution will NOT affect Iddq measurements or power consumption. For Iddq measurements the pull-ups can be switched off. Hence no testability feature of the design is compromised.

Having thus described at least one illustrative embodiment of the invention, various alterations, modifications, and improvements will readily occur to those skilled in the art. Such alterations, modifications, and improvements are intended to be within the scope of the invention. Accordingly, the foregoing description is by way of example only and is not intended as limiting. The invention is limited only as defined in the following claims and the equivalents thereto.

What is claimed is:

1. A pass gate multiplexer, comprising:
a decoder for selecting one out of a plurality of pass gates;
a weak pull-up at an output of said multiplexer for providing a defined logic level when all the pass gates are deselected; and
means for enabling or disabling said decoder,
to facilitate testing of internal select signals using externally generated test pattern vectors.

2. The pass gate multiplexer as claimed in claim 1 wherein said means is an electronic circuit connected to said decoder for enabling or disabling its output by an external enable/disable signal.

3. The pass gate multiplexer as claimed in claim 1 wherein said weak pull-up is controllable by logic signals so that it is disabled during normal operation and enabled only during testing.

4. A method of operating a pass gate multiplexer comprising:
providing a weak pull-up at an output of said multiplexer for obtaining a defined logic level when all the pass gates are deselected, and
making the internal decoder controllable by an enable/disable signal,
to facilitate the testing of the internal select signals using externally generated test pattern vectors.

5. A method as claimed in claim 4 wherein controlling of said weak pull-up is such that it is disabled during normal operation and enabled only during testing.
